(19) United States
(12) Patent Application Publication
(10) Pub. No.: US 2024/0351950 A1
(43) Pub. Date: Oct. 24, 2024

(54) SILANOL-BASED COMPOSITE COMPOSITION

(71) Applicant: Robert Bosch GmbH, Stuttgart (DE)

(72) Inventors: Stefan Henneck, Leonberg (DE); Tobias Kohler, Reutlingen (DE)

(21) Appl. No.: 18/683,012

(22) PCT Filed: Sep. 27, 2022
(86) PCT No.: PCT/EP2022/076857

§ 371 Date: Feb. 12, 2024

(30) Foreign Application Priority Data
Sep. 27, 2021 (DE) 10 2021 210 765.6
Jun. 8, 2022 (DE) 10 2022 205 823.2

(51) Int. Cl. C04B 26/32; C04B 14/30; C04B 40/02; C04B 111/92; H05K 1/03

(52) U.S. Cl. CPC C04B 26/32; C04B 14/303; C04B 40/0263; H05K 1/0306; C04B 2111/92

(57) ABSTRACT

A composite composition for forming a composite which can be used for potting electronics and/or electrics, in particular power electronics. To form a composite which is solid, in particular rigid, adhesive, in particular self-adhesive, thermally stable, and has a low coefficient of thermal expansion, high thermal conductivity and thermal diffusivity, and high thermal endurance, and protects and compressively stabilizes electronics and/or electrics and increases their lifespan and/or performance, the composite composition includes, relative to the total weight of the composite composition, ≥10 wt. % to ≤95 wt. % of at least one filler, and ≥1 wt. % to ≤15 wt. % of at least one silanol. A method for preparing a silanol composition; a corresponding silanol composition; a method for preparing the composite composition; a method for preparing a composite and/or a solid structure; a composite and/or a solid structure; and the use thereof, are also described.

### FIELD

The present invention relates to a composite composition for forming a composite, for example which can be used for potting electronics and/or electrics, in particular power electronics, a method for producing a silanol composition, a corresponding silanol composition, a method for producing the composite composition, a method for producing a composite and/or a solid structure, a composite, and/or a solid structure, and the use thereof.

### BACKGROUND INFORMATION

Power electronics modules, in particular in the form of frame modules, are nowadays usually potted with silicone gels in order to ensure the electrical insulation even at high voltages and small distances from the different electrical potentials.

Power electronics modules, for example electronic modules with low thermal loads and/or power electronics modules with a lower output, can also be potted with more or less rigid polymer compounds, for example filled epoxy resins or polyurethanes. However, encapsulating power electronics modules with such polymer compounds at high filling levels is usually only possible by injection molding at high pressure and high temperature. In addition, such polymer compounds often have a low thermal conductivity, for example of around ≤0.8-1 W/(m·K). In addition, inorganically bonded potting compounds are also available in the related art and are described, for example, in German Patent Application Nos. DE 10 2018 214 641 A1 and DE 10 2018 215 694 A1. However, such potting compounds are only self-adhesive to a limited extent so that an additional adhesion-promoting surface coating or primer coating on an organic basis is generally applied before casting.

Trialkoxysilanes can be used in the form of aqueous solutions with a very low trialkoxysilane content based on the total solution weight, for example ≤2 wt. %, and a very high water content, for example ≥98 wt. %, to form adhesion-promoting surface coatings or primer coatings. This is described, for example, in U.S. Pat. No. 6,824,880 B1.

A paper in J Sol-Gel Sci Technol, 2010, 55, 360-368 describes that the adhesion of epoxy resins can be improved by an adhesion-promoting surface coating made of a silane equipped with a functional group.

A paper in J Coat, Technol. Res., 2016, 13 (6), 1035-1046, and PCT Patent Application No. WO 2020/057174 A1 describe water-based anticorrosion coating agents based on silanes. China Patent Application No. CN 2020/22980 U describes an aluminum material with a nanoceramic silane composite film on the surface.

### SUMMARY

The present invention relates to a composite composition for forming a composite which contains, based on the total weight of the composite composition,
≥10 wt. % to ≤95 wt. % of at least one filler, and
≥1 wt. % to ≤15 wt. % of at least one silanol.

A composite composition for forming a composite can in particular be understood to mean a composition that can be solidified, in particular cured, to form a composite.

A silanol can in particular be understood to mean a silane derivative in which a hydroxyl group (OH group) or multiple hydroxyl groups (OH groups) is or are bonded to a silicon atom.

According to an example embodiment of the present invention, the composite composition can in particular be flowable and/or pourable, for example before the solidification, for example curing, thereof. The composite composition can therefore be used in particular for casting and/or for coating and/or for potting. The composite composition can particularly advantageously be used for potting. The composite composition can therefore also be referred to as a potting compound. In particular, the composite composition can also be used for potting, for example for encapsulating, electronics and/or electrics, for example also for potting, for example for encapsulating, power electronics, for example power electronics modules, in particular in the form of frame modules. In this case, the potting compound can advantageously also be used for potting electronics and/or electrics by means of the glob-top technique and/or the dam-and-fill technique.

Silanols can advantageously react with OH groups on material surfaces, particularly at temperatures of ≥130° C. to ≤250° C., by means of a condensation reaction by splitting off water, thereby forming a strong chemical bond, in particular a covalent bond. Filler materials generally have at least a small fraction of OH groups on their surface, whether because the filler material itself is already an oxygen-containing, for example ceramic, for example oxidic and/or siliceous, material or a material that is, for example, essentially oxygen-free, for example a ceramic and/or metallic material, but that has an oxidized surface having OH groups due to degradation phenomena, for example by reaction with atmospheric humidity, such as other types of ceramic materials such as nitrides, for example aluminum nitride and/or boron nitride, and/or metals, such as copper, silver, gold, nickel, aluminum, iron et cetera, and/or semimetals, such as silicon, and/or carbon modifications. This makes it possible for the at least one silanol with OH groups on the surface of the at least one filler to react by means of a condensation reaction by splitting off water and thereby to form a strong chemical, in particular covalent, bond to the surface of the at least one filler. In addition, most materials used in the field of electronics and/or electrics and/or assembly and packaging technology, for example metals such as copper, silver, gold, nickel, aluminum, etc., and/or semiconductors such as silicon, and/or ceramic materials such as silicon dioxide and/or aluminum oxide, have a surface which has OH groups, in particular due to degradation phenomena such as reaction with atmospheric humidity, and enables the at least one silanol to also react therewith by means of a condensation reaction by splitting off water and also to form a strong chemical, in particular covalent, bond to the surface of such substrates, for example electronic and/or electrical components. In addition, the hydroxyl groups of silanols can advantageously also react with one another, especially at temperatures of ≥130° C. to ≤250° C., by means of a condensation reaction by splitting off water and thereby form a polymeric structure.

In this way, the at least one silanol in the composite composition advantageously makes it possible to form, in particular at a temperature in a range of ≥130° C. to ≤250° C., a very solid, strongly adhesive, in particular self-adhesive, and thermally stable composite on the basis of an Si—O—Si—O structure with strong chemical bonds to the at least one filler and possibly also to a surface in contact with said filler, for example a surface of a substrate, for example of an electronic and/or electrical component, on and/or with which the composite composition was cast and/or potted and/or coated, which composite in particular can also be used at operating temperatures above 200° C. and, for example, also with long-term thermal loads up to 300° C.

Since the at least one silanol of the composite composition itself can already react with OH groups on substrate surfaces to form strong chemical, in particular covalent, bonds, the application of an additional adhesion-promoting layer can also advantageously be omitted. The composite composition can thus advantageously be used as a single-system casting. As a result, process steps can advantageously be reduced and preparation methods can be simplified.

In the composite, the at least one silanol can in particular form a close-meshed and in particular also three-dimensional network, as a result of which the composite formed therefrom can advantageously on the one hand have high strength, in particular rigidity and hardness, for example which can exceed those of conventional thermally crosslinking polysiloxane resins, and on the other hand have little or no thermoplastic softening, in particular no glass transition temperature recognizable in the dilatometer.

Because the at least one filler makes up a comparatively high weight percentage, for example of ≥10 wt. % to ≤95 wt. %, in particular of ≥60 wt. % to ≤95 wt. %, and thus in particular can also make up a high volume fraction of the composite composition and of the composite formed therefrom, and because, in this regard, the at least one silanol makes up a rather low weight percentage of ≥1 wt. % to ≤15 wt. %, in particular of ≥2 wt. % to ≤12 wt. %, and in particular also volume fraction of the composite composition and the composite formed therefrom, a low shrinkage and a low coefficient of thermal expansion or thermal expansion coefficient, in particular with high rigidity at the same time, can also advantageously be realized, which can be particularly advantageous in particular in the potting of bulky structures and in particular electronics, such as power electronics.

The composite composition can be used, inter alia, particularly advantageously for potting electronics and/or electrics, such as power electronics, since due to the low coefficients of thermal expansion, for example in a range of 7-9·10⁻⁶ K⁻¹, for example with respect to metals of conductor tracks and/or a printed circuit board assembly, and also the high strength and the high adhesive strength of the composite formed therefrom, thermally induced deformations and/or relative movements, for example of printed circuit boards or printed circuit board assemblies, bonding wires, chips, and solders, which occur in particular in the case of high electrical loads and thereby generated heat loss in conventional electronic pottings and in the long term can lead to a decomposition of layers and connections, are impeded. Thus, by means of the composite formed from the composite composition, a compressive stabilization or fixing of the construction and connection technology on the substrate, for example on the printed circuit board, for example of a bonding layer, for example a solder layer and/or sinter layer, for example between semiconductor chips and printed circuit board, and/or of wire or ribbon bonding connections, for example in the case of thermal cycling, can advantageously be achieved, and, for example, a thermal delamination and, for example, a so-called bonding wire lift-off can be prevented. Electronics can thus also be protected from thermomechanical influences in addition to mechanical influences by the composite formed from the composite composition. In this case, the composite formed from the composite composition can have high thermal stability and high thermal endurance, for example of above 180° C. up to 260° C. (junction temperature), in comparison with epoxy-based potting compounds. This in turn advantageously makes it possible, by potting with the composite composition, to increase the lifespan of electronics and/or electrics, in particular power electronics, significantly, for example by a factor of 3 in comparison with conventional potting compounds for this purpose.

In addition, silanols are advantageously of low viscosity, which, for example in contrast to polysiloxane- or silicone elastomer-based potting compounds, makes it possible to provide a highly flowable composite composition even with a very high filling level at the at least one filler and in particular also with a wide granulation band of the at least one filler and/or also with fillers having large particles, for example in a range of ≥1 μm to ≤200 μm, which composite composition advantageously can also be processed, in particular cast and/or potted, without pressure, i.e., using gravity, and/or without the need of a vacuum and/or without the need of warming the potting compound during potting.

Furthermore, the low viscosity of the at least one silanol and the low weight percentage or volume fraction thereof makes it possible to chemically connect the particles of the at least one filler to one another via very thin structures, for example layers, formed from the at least one silanol, whereby a high thermal conductivity, in particular above 5 W/(m·K), and an improved thermal diffusivity can be achieved within the composite formed therefrom, which can in particular be significantly higher than the thermal conductivity and thermal diffusivity of conventional polysiloxane- or silicone elastomer-based potting compounds and/or silicone gels that can be potted cold and without pressure, and/or unfilled and filled polyurethanes and/or epoxy resins, the two latter of which in particular can generally only reach thermal conductivities of up to about 2.5 W/(m·K). For power electronics, in particular a high thermal conductivity and thermal diffusivity are needed for effective heat dissipation, for which reason the composite composition can be used particularly advantageously for potting them. In particular on power electronics modules with so-called “bare die” semiconductor chips which are constructed on ceramic printed circuit boards, for example DBC (direct bonded copper), AMB (active metal brazed), LTCC (low-temperature co-fired ceramic), etc., the composite composition enables a significant increase in the lifespan, for example by at least a factor of 3 in comparison with an identical structure with a conventional silicone gel potting, and can allow higher continuous operating temperatures, for example of above 180° C., at the semiconductors. Since the performance of SiC semiconductors, for example in the case of frame modules with power electronics, is limited in particular by the level of the continuous operating temperature, and the composite composition enables higher continuous operating temperatures, for example of above 180° C., the performance of SiC semiconductors, for example in the case of frame modules with power electronics, can thus advantageously also be increased by the composite composition.

Since the condensation reaction of the at least one silanol effectively only occurs at high temperatures, in particular of ≥130° C. to ≤250° C., the composite composition can advantageously have a long pot life, for example of several days, at moderate temperatures, for example at room temperature, in a closed system, which is particularly advantageous in particular for process development in series production. In order to counteract a filler sedimentation during the pot life, the composite composition can, for example, be stirred continuously or stirred at least before its use.

Since the condensation reaction of the at least one silanol effectively only occurs at high temperatures, in particular of ≥130° C. to ≤250° C., the composite composition can first be dried at low temperatures, for example in a range of ≥0° C. to ≤90° C., in particular using a negative pressure, after its application, for example after casting and/or potting and/or coating, in particular before curing at a high temperature, for example of ≥130° C. to ≤250° C. For example, volatile solvents therein, for example organic solvents such as alcohols and/or water, can be removed in the process. During drying, the composite composition can advantageously remain deformable and adapt its shape to its surroundings, for example to the shape of a substrate potted and/or coated therewith, for example an electronic and/or electrical component. Mechanical stresses and, for example, crack formation can thus be minimized. In addition, because the composite composition is dried before curing, the time in which the substrate, for example electronics, potted and/or coated with the composite composition is in contact with solvents contained therein, in particular water, can be minimized.

Overall, a composite composition can thus advantageously be provided which can be used in a simple manner for casting and/or potting and/or coating, for example for encapsulating, in particular for potting, for example electronics and/or electrics, in particular power electronics, and from which a solid, in particular rigid, adhesive, in particular self-adhesive, and thermally stable composite can be formed with a low coefficient of thermal expansion, with a high thermal conductivity and/or thermal diffusivity, and with a high thermal endurance. The composite composition can be used particularly advantageously for potting electronics and/or electrics, in particular power electronics, wherein, by means of the composite formed therefrom, the electronics and/or electrics can be protected and in particular compressively stabilized and/or the lifespan and/or performance thereof can be increased.

In one embodiment of the present invention, the composite composition comprises <10 wt. % of water based on the total weight of the composite composition. For example, the composite composition can comprise ≥0 wt. % to ≤10 wt. %, for example ≥0 wt. % to ≤5 wt. %, in particular ≥0 wt. % to ≤2 wt. %, of water, based on the total weight of the composite composition.

In the context of the present invention, the lowest possible water content has proven to be particularly advantageous. On the one hand, this is because, due to the lowest possible water content of the composite composition, the drying and curing thereof can be realized more quickly and more energy-efficiently. On the other hand, the time of action of the water during which substrates to be equipped, for example electronics and/or electrics, for example power electronics, which may possibly be water-sensitive, are in contact therewith, can thus be minimized and as a result the substrate to be equipped can be protected.

The at least one filler can in principle be a (single) filler or a combination of two or more fillers.

As explained above, the at least one filler can in particular have a surface having OH groups. Ceramic and/or metallic fillers generally have at least a small proportion of OH groups on their surface. A ceramic filler can in particular be understood to mean a non-metallic inorganic filler. As already explained, this can be the case, for example in ceramic, for example oxidic and/or siliceous, fillers due to an oxygen-containing composition of the filler as such, for example of aluminum oxide, silicon dioxide, etc. In other ceramic fillers, for example nitride fillers, and/or in metallic fillers, for example based on copper, silver, gold, nickel, aluminum, iron et cetera, the surface can likewise have OH groups. This can be based, for example, on an oxide shell that is produced natively on air contact and can be formed, for example, by reaction with atmospheric humidity and/or by targeted thermally assisted treatment with oxygen and water.

In a further embodiment of the present invention, the at least one filler therefore comprises at least one ceramic and/or metallic filler. In particular, the at least one filler can be a ceramic and/or metallic filler.

For certain applications in which the properties of metallic fillers are advantageous, for example in order to prepare an electrically conductive and/or catalytically active and optionally also thermally conductive composite, the at least one filler can, for example, comprise or be at least one metallic filler.

For other applications in which the properties of ceramic fillers are advantageous, for example in order to prepare an electrically insulating and/or thermally conductive composite, the at least one filler can in particular comprise or be at least one ceramic filler.

Due to electrical insulation properties, ceramic fillers have proven to be particularly advantageous for application of the composite composition to electrics and/or electronics, for example power electronics.

In a further embodiment of the present invention, the at least one filler therefore comprises at least one ceramic filler. In particular, the at least one filler can be a ceramic filler.

In a further embodiment of the present invention, the at least one filler comprises at least one oxidic and/or nitridic and/or carbidic and/or siliceous filler. In particular, the at least one filler can be at least one oxidic and/or nitridic and/or carbidic and/or siliceous filler.

Oxidic and/or nitridic and/or carbidic and/or siliceous fillers can advantageously be both thermally conductive and electrically insulating and additionally have advantageous coefficients of thermal expansion. For this reason, oxidic and/or nitridic and/or carbidic and/or siliceous fillers can be used particularly advantageously for the application of the composite composition to electronics and/or electrics. Oxidic and/or nitridic and/or carbidic and/or siliceous fillers can in particular also provide electrical insulation (high-voltage insulation) in the case of high voltages and short distances between different electrical potentials. For this reason, oxidic and/or nitridic and/or carbidic and/or siliceous fillers can in particular be used particularly advantageously for the application of the composite composition to power electronics.

In particular, the at least one filler can be free of alkali ions and halide ions for application of the composite composition to electronics and/or electrics, in particular power electronics. The electrical insulation and the lifespan of the electrics and/or electronics can thus advantageously be improved further.

In one embodiment of the present invention, the at least one filler comprises at least one oxidic and/or siliceous filler. In particular, the at least one filler can be an oxidic and/or siliceous filler.

Due to the oxygen-containing composition of the filler as such, oxidic and/or siliceous fillers advantageously have a particularly high proportion of OH groups. A particularly high degree of bonding of the at least one filler in the composite can thus advantageously be achieved, whereby a high mechanical stability and/or thermal conductivity of the composite can in turn be achieved.

In a further embodiment of the present invention, the at least one filler comprises aluminum oxide (Al₂O₃) and/or silicon dioxide (SiO₂) and/or magnesium oxide (MgO) and/or zinc oxide (ZnO) and/or zirconium oxide (ZrO₂) and/or forsterite (Mg₂SiO₄) and/or aluminum nitride (AlN) and/or boron nitride (BN) and/or silicon nitride (Si₃N₃). For example, the at least one filler can be aluminum oxide and/or silicon dioxide and/or magnesium oxide and/or zirconium oxide and/or forsterite and/or aluminum nitride and/or boron nitride and/or silicon nitride.

With regard to their high thermal conductivity, their high electrical insulation capacity, in particular which is also suitable for high-voltage insulation, and their coefficients of thermal expansion, these fillers have proven to be particularly advantageous for the application of the composite composition to electronics and/or electrics, in particular power electronics.

In particular, the at least one filler can comprise aluminum oxide and/or silicon dioxide and/or magnesium oxide and/or zirconium oxide and/or forsterite. For example, the at least one filler can be aluminum oxide and/or silicon oxide and/or magnesium oxide and/or zirconium oxide and/or forsterite. A particularly high degree of bonding of the at least one filler in the composite can thus advantageously be achieved, whereby a high mechanical stability and/or thermal conductivity of the composite can in turn be achieved.

In a specific embodiment of the present invention, the at least one filler comprises aluminum oxide. For example, the at least one filler can be aluminum oxide, for example aluminum oxide free of alkali ions and halide ions, for example high-purity aluminum oxide.

Aluminum oxide advantageously has a high thermal conductivity, a high electrical insulation capacity, in particular which is also suitable for high-voltage insulation, and a coefficient of thermal expansion suitable for electronics and/or electrics, in particular power electronics, and a high proportion of OH groups on the surface in order to achieve a high degree of bonding, and is also advantageously comparatively inexpensive.

In the context of the present invention, it has surprisingly been found that the at least one silanol in a comparatively small amount of ≥1 wt. % to ≤15 wt. %, in particular of ≥2 wt. % to ≤12 wt. %, based on the total weight of the composite composition, allows high to very high filling levels of the at least one filler to be realized. For example, the composite composition can comprise, based on the total weight of the composite composition, ≥15 wt. % or ≥20 wt. % or ≥25 wt. % or ≥30 wt. % or ≥35 wt. % or ≥40 wt. % or ≥45 wt. % or ≥50 wt. % or ≥55 wt. %, for example up to ≤95 wt. % or ≤94 wt. % or ≤93 wt. % or ≤92 wt. %, optionally to ≥91 wt. % or ≤90 wt. % of the at least one filler.

Due to a high filling level of the at least one filler, the mechanical stability, the thermal conductivity, the electrical insulation capacity and the thermal expansion coefficient of the composite formed from the composite composition can advantageously be further optimized, and in particular a shrinkage of the composite composition during curing to form the composite can be minimized.

In a further embodiment of the present invention, the composite composition therefore comprises, relative to the total weight of the composite composition, ≥60 wt. % to ≤95 wt. % of the at least one filler.

In particular, the composite composition can comprise, relative to the total weight of the composite composition, ≥61 wt. % or ≥62 wt. % or ≥63 wt. % or ≥64 wt. % or ≥65 wt. % or ≥66 wt. % or ≥67 wt. % or ≥68 wt. % or ≥69 wt. %, for example ≥70 wt. % or ≥71 wt. % or ≥72 wt. % or ≥73 wt. % or ≥74 wt. % or ≥75 wt. % or ≥76 wt. % or ≥77 wt. % or ≥78 wt. % or ≥79 wt. %, for example ≥80 wt. % or ≥81 wt. % or ≥82 wt. % or ≥83 wt. % or ≥84 wt. % or ≥85 wt. %, optionally ≥86 wt. % or ≥87 wt. % or ≥88 wt. %, to ≤ 95 wt. %, for example to ≤94 wt. % or ≤93 wt. %, for example to ≤92 wt. %, of the at least one filler.

In a specific embodiment of the present invention, the composite composition comprises, based on the total weight of the composite composition, ≥85 wt. %, for example ≥86 wt. % or ≥87 wt. %, for example ≥88 wt. %, to ≤95 wt. %, for example up to ≤94 wt. % or ≤93 wt. %, for example up to ≤92 wt. %, of the at least one filler.

This has proven to be particularly advantageous with regard to the mechanical stability, the thermal conductivity, the electrical insulation capacity and the thermal expansion coefficient of the composite formed from the composite composition, as well as to a minimization of the shrinkage of the composite composition during curing to form the composite.

For example, the composite composition can comprise, relative to the total weight of the composite composition, ≥88 wt. % to ≤92 wt. % of the at least one filler.

The at least one filler can, for example, have a D50 value (or median of the grain sizes) in a range of ≥0.1 μm to ≤110 μm and/or a granulation band, in particular between the smallest and the largest grain, in a range of ≥0.05 μm to ≤200 μm and/or a maximum grain size of ≤200 μm.

In a further embodiment of the present invention, the at least one filler comprises at least one coarse filler and at least one fine filler.

In this case, gaps between particles of the at least one coarse filler can advantageously be filled up by the at least one fine filler. Thus, a particularly high filling level can advantageously be achieved and thereby properties of the composite formed from the composite composition, such as the mechanical stability and/or the thermal expansion coefficient and/or the thermal conductivity and/or the electrical insulation capacity, can be further improved, and the shrinkage during curing of the composite composition to form the composite can be further minimized.

In a specific form of this embodiment of the present invention, the at least one coarse filler has a granulation band, in particular between the smallest and the largest grain, in a range of ≥1 μm to ≤200 μm, and/or a D50 value (or median of the grain sizes) in a range of ≥5 μm to ≤110 μm, for example in a range of ≥10 μm to ≤40 μm.

In a further specific, alternative or additional, in particular additional, form of this embodiment of the present invention, the at least one fine filler has a granulation band, in particular between the smallest and the largest grain, in a range of ≥0.05 μm to ≤1 μm, and/or a D50 value (or median of the grain sizes) in a range of ≥0.1 μm to ≤0.9 μm, for example in a range of ≥0.1 μm to ≤0.2 μm.

This has proven to be particularly advantageous for achieving a high filling level and for improving properties of the composite formed from the composite composition, such as the mechanical stability and/or the thermal expansion coefficient and/or the thermal conductivity and/or the electrical insulation capacity, and for minimizing shrinkage during curing of the composite composition to form the composite.

In a further embodiment of the present invention, the composite composition comprises, relative to the total weight of the composite composition,
≥60 wt. % to ≤90 wt. % of the at least one coarse filler and
≥0 wt. % to ≤8 wt. % of the at least one fine filler.

This has proven to be particularly advantageous for achieving a high filling level and for improving properties of the composite formed from the composite composition, such as the mechanical stability and/or the thermal expansion coefficient and/or the thermal conductivity and/or the electrical insulation capacity, and for minimizing shrinkage during curing of the composite composition to form the composite. Through a combination of the two embodiments explained above, the packing density and thereby the filling level and the advantages achievable thereby can advantageously be optimized further.

The composite composition can, for example, comprise, relative to the total weight of the composite composition, ≥2 wt. % to ≤12 wt. % of the at least one silanol. The composite composition can, for example, comprise, relative to the total weight of the composite composition, ≥3 wt. % to ≤11 wt. % of the at least one silanol. In particular, the composite composition can comprise, relative to the total weight of the composite composition, ≥5 wt. % to ≤10 wt. % of the at least one silanol. This has proven to be particularly advantageous in the context of the present invention.

The at least one silanol can, for example, be a (single) silanol or a combination of two or more identical or different silanols.

In a further embodiment of the present invention, the at least one silanol comprises at least one silanetriol. A silanetriol can in particular be understood to be a silanol in which three hydroxyl groups are bonded to a silicon atom. Silanetriols can also be referred to, for example, as trihydroxysilanes. The fact that the at least one silanol comprises at least one silanetriol has proven to be advantageous in terms of mechanical stability and/or coefficient of thermal expansion and/or thermal conductivity and/or electrical insulation capacity.

The fact that the at least one silanetriol has three hydroxyl groups means that it can advantageously form a three-dimensional, in particular polymeric, network based on Si—O—Si—O structures within the composite, in particular by means of a condensation reaction of the hydroxyl groups. Thus, advantageously, both a particularly high degree of crosslinking, in particular within the three-dimensional, in particular polymeric, network based on Si—O—Si—O structures and formed by the condensation reaction of the hydroxyl groups, and a high degree of bonding, in particular of the three-dimensional, in particular polymeric, network based on Si—O—Si—O structures and formed by the condensation reaction of the hydroxyl groups, to the particles of the at least one filler, and, for example when the composite composition comes into contact with a surface having OH groups, for example a metallic and/or ceramic surface, to this surface as well can be achieved. In this way, the mechanical stability and/or the adhesive strength on the surface and/or the thermal expansion coefficient and/or the thermal conductivity and/or the electrical insulation capacity of the composite and the lifespan of components equipped therewith, for example electronics and/or electrics potted therewith, in particular power electronics, can be further optimized.

The at least one silanetriol can in particular be the main constituent of the at least one silanol.

As explained in more detail below, the at least one silanol can be produced in particular by hydrolysis of at least one trialkoxysilane. In particular, the at least one silanol can comprise at least one silanetriol as the main constituent. The at least one silanetriol can, for example, be formed by complete hydrolysis of the at least one trialkoxysilane. In addition to the at least one silanetriol as the main constituent, the at least one silanol can optionally also comprise other, in particular not yet fully hydrolyzed or only partially hydrolyzed alkoxysilanols, for example at least one, for example only partially hydrolyzed, alkoxysilanol as secondary constituent(s). Advantageously, it has been found that, in particular also in the case of a composite composition which as such is low in water or is anhydrous, such secondary constituents can still hydrolyze and then condense again in the later condensation reaction during curing of the composite composition, since water is released in the condensation reaction during curing of the composite composition, by means of which water not-yet-hydrolyzed alkoxy groups of alkoxysilanols contained in the at least one silanol and only partially hydrolyzed up to that point are subsequently hydrolyzed to form hydroxyl groups, with the release of alcohol, and can then be condensed again with the release of water.

In a further embodiment of the present invention, the at least one silanol, in particular the at least one silanetriol, has an organic moiety. The at least one silanol, in particular the at least one silanetriol, can comprise or be a silanol which is simply substituted with an organic moiety, for example silanetriol. The organic moiety can advantageously modify properties of the composite composition and/or the composite formed therefrom. For example, the chain length of the organic moiety can be used to adjust the elasticity of the composite formed.

For example, the organic moiety can have a chain length of ≥1 atom, in particular a chain length of ≥2 atoms or of ≥3 atoms, for example a chain length of ≥4 or ≥5 or ≥6 atoms, for example a chain length of ≥7 atoms. In this way, the elasticity of the cured composite can be advantageously adjusted and formation of microcracks can, for example, be avoided.

In principle, the organic moiety can comprise a group which is unreactive as such, for example an alkyl group, for example a methyl, ethyl or propyl group, and/or an alkylene chain, for example a methylene, ethylene or propylene chain, and/or an aryl group, for example a phenyl group. For example, the organic moiety can be an alkyl group, for example a methyl group or an ethyl group or a propyl group, and/or an aryl group, for example a phenyl group.

In a further specific, alternative or additional form of this embodiment of the present invention, however, the organic moiety has at least one functional group, i.e., at least one reactive group. The at least one functional group on the organic moiety of the at least one silanol, in particular silanetriol, can also advantageously modify properties of the composite composition and/or the composite formed therefrom. For example, the adhesion of the composite composition and the composite formed therefrom to particular substrates and possibly also to the at least one filler can be further improved in this way.

For example, the at least one functional group of the organic moiety of the at least one silanol, in particular silanetriol, can comprise or be an epoxy group and/or an amino group and/or a mercapto group and/or a vinyl group. The at least one functional group can advantageously further improve the bonding of the, in particular polymeric, network formed, in particular by means of a condensation reaction, of the at least one silanol, to a substrate, for example a metallic substrate, and/or optionally also to the at least one filler.

For example, the at least one functional group of the organic moiety of the at least one silanol, in particular silanetriol, can comprise or be an epoxy group. The at least one silanol can in particular be an epoxysilanol. The at least one silanetriol can in particular be an epoxysilanetriol or an epoxytrihydroxysilane.

Alternatively or additionally, the at least one functional group of the organic moiety of the at least one silanol, in particular silanetriol, can comprise or be, for example, an amino group. In particular, the at least one silanol can be an aminosilanol. The at least one silanetriol can in particular be an aminosilanetriol or an aminotrihydroxysilane.

Alternatively or additionally, the at least one functional group of the organic moiety of the at least one silanol, in particular silanetriol, can comprise or be, for example, a mercapto group. The at least one silanol can in particular be a mercaptosilanol. The at least one silanetriol can in particular be a mercaptosilanetriol or a trihydroxymercaptosilane.

Alternatively or additionally, the at least one functional group of the organic moiety of the at least one silanol, in particular silanetriol, can comprise or be, for example, a vinyl group. In particular, the at least one silanol can be a vinyl silanol. The at least one silanetriol can in particular be a vinylsilanetriol or a trihydroxyvinylsilane.

The at least one silanol, in particular the at least one silanetriol, can, for example, be a (single) silanol, in particular silanetriol, or a combination of two or more different silanols, in particular silanetriols, for example a combination of a first silanol, in particular silanetriol, with a first organic moiety, for example with a first functional group and/or with a first chain length, for example (3-glycidyloxypropyl) silanetriol or 3-mercaptopropylsilanetriol, and a second silanol, in particular silanetriol, with a second organic moiety, in particular different from the first organic moiety, for example with a second functional group and/or with a second chain length, for example 3-mercaptopropylsilanetriol or (3-glycidyloxypropyl) silanetriol, and/or for example optionally also with an unreactive group, such as an alkyl group and/or an aryl group, for example methylsilanetriol.

The at least one silanol or the at least one silanetriol can in principle be obtained from standard chemical suppliers. However, commercially available silanols and silanetriols are generally marketed in the form of aqueous silanol solutions having a high water content, for example of ≥70 wt. %, relative to the total weight of the silanol solution. As already explained above, however, the lowest possible water content in the composite composition has proven to be advantageous with regard to the speed and energy efficiency of the drying and curing thereof.

In order to be able to use silanols with the lowest possible water content in the composite composition, a production method, which is explained in more detail below, for a silanol composition, which is explained in more detail below, was therefore developed within the framework of the present invention, in which production method at least one trialkoxysilane and water, forming the at least one silanol, in particular silanetriol, and at least one alcohol are mixed, in particular in a closed system, for example at a temperature of ≥60° C., for example of ≥70° C., in particular at a temperature in a range of ≥60° C., for example of ≥70° C., in particular up to ≤100° C., which makes it possible to obtain a silanol low in water by adding an amount of water that is only slightly overstoichiometric for the desired degree of hydrolysis or, if necessary, even an anhydrous silanol by adding an amount of water that is stoichiometric for the desired degree of hydrolysis or, if necessary, even an amount of water that is slightly understoichiometric for the desired degree of hydrolysis, and in this way to minimize the water content in the composite composition.

In a further embodiment of the present invention, therefore, the at least one silanol and/or the at least one alcohol explained below, for example the at least one silanol and the at least one alcohol explained below, are contained in the form of a silanol composition according to the present invention, for example explained in more detail below, in the composite composition. Here the silanol composition can in particular comprise at least one silanol and at least one alcohol. The silanol composition can here be produced, for example, by converting a mixture of at least one trialkoxysilane and water.

During mixing, the alkoxy groups of the at least one trialkoxysilane can be hydrolyzed by the water, forming hydroxyl groups (instead of the alkoxy group) on the silicon atom of the silane and thus forming the at least one silanol, in particular the at least one trihydroxysilanol, and forming at least one alcohol.

Due to the formation of the hydroxyl groups, the formed silanol advantageously becomes soluble, in particular not only in water but in particular also in the alcohol forming from hydrolyzed alkoxy groups of the trialkoxysilane, which makes it possible to use the formed, alcohol-dissolved silanol directly in the form of the formed alcoholic solution in the composite composition.

By minimizing the amount of water used in the mixture, it can advantageously be achieved that the resulting silanol composition contains only a small or possibly even no significant amount of water, which can have an advantageous effect on the composite composition, as already explained.

For example, the mixture used to produce the silanol composition, based on the total weight of the mixture, can comprise
≥70 wt. % to ≤90 wt. %, in particular ≥75 wt. % to ≤90 wt. %, for example ≥76 wt. % to ≤85 wt. %, of the at least one trialkoxysilane, and
≥10 wt. % to ≤30 wt. %, for example ≥10 wt. % to ≤25 wt. %, in particular ≥15 wt. % to ≤24 wt. %, of water.

In order to minimize the water content of the silanol composition and thus of the composite composition, an amount of water by which at least a large part of the alkoxy groups, in particular all the alkoxy groups, of the at least one trialkoxysilane is converted to hydroxyl groups of the at least one silanol, in particular silanetriol, and/or which is completely converted to hydroxyl groups of the at least one silanol, in particular silanetriol, is preferably used in the mixture for producing the silanol composition.

This can be achieved in particular by using the water in a stoichiometric amount or at most in a slightly overstoichiometric amount, for example by a factor of ≤1.7, for example ≤1.5, in particular ≤1.3, for example ≤1.1, but preferably in a stoichiometric amount, in particular with a factor of 1, to the alkoxy groups of the at least one trialkoxysilane.

By using the water in such an amount to the alkoxy groups of the at least one trialkoxysilane, the at least one silanol, in particular the at least one silanetriol, can advantageously be used in the form of a low-water, almost anhydrous, alcoholic solution in the composite composition, which has proven to be particularly advantageous for processing and/or for faster and more energy-saving drying and/or curing of the composite composition.

The conversion of a mixture can take place in particular in a closed system. It can thus advantageously be brought about that the alcohol that forms and also the water required for the reaction remain in the mixture (until the conversion of the water).

In particular, the mixing can take place at a particular temperature and/or for a particular period of time.

In particular, the mixing can take place at a temperature of ≥60° C., for example of ≥70° C., in particular up to ≤100° C. The hydrolysis reaction can advantageously be accelerated by a temperature of ≥60° C., for example of ≥70° C. By limiting the temperature to below 100° C., premature condensation reactions can advantageously be avoided.

If the selected temperature is above the boiling point of the alcohol that is to be formed, the closed system can in particular be pressure-resistant and/or designed as an autoclave.

The particular time for which the mixture is mixed is based in particular on the selected temperature. When mixing at a temperature of 70° C., the mixture can already become clear after 45 minutes, which basically indicates the formation of silanols, but in order to form silanetriols, the mixture is mixed at 70° C. for at least 3 hours, for example up to one day. At higher temperatures, the time required for mixing is shortened according to the applied temperature.

The alcohol that forms is preferably not removed from the mixture or remains in the mixture. Further water is also preferably not added.

The at least one trialkoxysilane can, for example, comprise or be at least one trimethoxysilane and/or at least one triethoxysilane and/or at least one tripropoxysilane and/or at least one tributoxysilane. For example, the at least one alcohol can comprise or be methanol and/or ethanol and/or propanol, for example isopropanol and/or n-propanol, and/or butanol, for example tert-butanol and/or sec-butanol and/or isobutanol and/or n-butanol.

For example, the at least one trialkoxysilane can comprise or be at least one triethoxysilane and/or at least one tripropoxysilane and/or at least one tributoxysilane. The at least one alcohol can, for example, comprise or be ethanol and/or propanol, for example isopropanol and/or n-propanol, and/or butanol, for example tert-butanol and/or sec-butanol and/or isobutanol and/or n-butanol. These trialkoxysilanes have proven to be advantageous with regard to low toxicity and good processability of the alcohol formed therefrom in the composite composition.

For example, the at least one trialkoxysilane can comprise or be at least one triethoxysilane and/or at least one tripropoxysilane. The at least one alcohol can, for example, comprise or be ethanol and/or propanol, for example isopropanol and/or n-propanol.

In particular, the at least one trialkoxysilane can comprise or be at least one triethoxysilane. The at least one alcohol can in particular comprise or be ethanol. These trialkoxysilanes have proven to be advantageous with regard to low toxicity, good processability of the alcohol formed therefrom in the composite composition and low production costs.

The at least one trialkoxysilane can further comprise or be, analogously to that explained above, in particular an organic moiety, for example with a chain length of ≥1 atom, for example with a chain length of ≥2 atoms or ≥3 atoms, for example with a chain length of ≥4 or ≥5 or ≥6 atoms, for example with a chain length of ≥7 atoms, and/or with at least one functional group, for example with at least one epoxy group and/or amino group and/or mercapto group and/or vinyl group, in particular epoxy group. For example, the at least one trialkoxysilane can comprise or be (3-glycidyloxypropyl)triethoxysilane (GLYEO).

As a result of its production, the silanol composition produced in this way comprises a high alcohol fraction and can advantageously be used both for the provision of the at least one silanol in the composite composition according to the present invention and/or as a composite composition additive, and, as such, as a casting compound for application on a, in particular metallic and/or ceramic, material, and/or with at least one, in particular ceramic and/or metallic, filler. For example, the silanol composition as such can be used as a casting compound for coating and/or for potting a, in particular metallic and/or ceramic, material, and/or at least one, in particular ceramic and/or metallic, filler.

For example, a silanol composition prepared from the amounts of trialkoxysilane and water indicated above can comprise, based on the total weight of the silanol composition,
≥30 wt. % to ≤70 wt. %, for example ≥35 wt. % to ≤65 wt. %, in particular ≥40 wt. % to ≤60 wt. %, of at least one silanol, ≥25 wt. % to ≤70 wt. %, for example ≥30 wt. % to ≤65 wt. %, in particular ≥40 wt. % to ≤60 wt. %, of at least one alcohol, for example, in particular in total, of methanol and/or ethanol and/or propanol, for example isopropanol and/or n-propanol, and/or butanol, for example tert-butanol, sec-butanol and/or isobutanol and/or n-butanol, and
≥0 wt. % to ≤20 wt. %, for example ≥0 wt. % to ≤15 wt. % or ≤10 wt. %, in particular ≥0 wt. % to ≤5 wt. %, of water.

In particular, the percentage by weight of the at least one silanol, the percentage by weight of the at least one alcohol and the percentage by weight of water can in total yield 100 percent by weight, or the silanol composition can consist of
≥30 wt. % to ≤70 wt. %, for example ≥35 wt. % to ≤65 wt. %, in particular ≥40 wt. % to ≤60 wt. %, of at least one silanol,
≥25 wt. % to ≤70 wt. %, for example ≥30 wt. % to ≤65 wt. %, in particular ≥40 wt. % to ≤60 wt. %, of at least one alcohol, and
≥0 wt. % to ≤20 wt. %, for example ≥0 wt. % to ≤15 wt. % or ≤10 wt. %, in particular ≥0 wt. % to ≤5 wt. %, of water,
   based on the total weight of the silanol composition.

In a further embodiment of the present invention, the composite composition therefore comprises at least one alcohol.

The addition of at least one alcohol, for example instead of water, has proven to be particularly advantageous both for processing and for drying and/or curing of the composite composition. The flow properties of the composite composition can advantageously be adjusted by the at least one alcohol, for example for use as a potting compound for electronics and/or electrics. In the event of an addition of the at least one silanol to the composite composition in the form of a silanol composition according to the present invention, it is thus also advantageously possible to dispense with the removal of the alcohol during the production of the silanol composition, thereby also simplifying the production method.

For example, the at least one alcohol can in principle comprise or be methanol and/or ethanol and/or propanol, for example isopropanol and/or n-propanol, and/or butanol, for example tert-butanol, sec-butanol, and/or isobutanol and/or n-butanol.

These alcohols advantageously have a low viscosity and have proven particularly advantageous for forming a composite composition with a low viscosity, in particular even at high filling levels, for example of over 60 wt. % and in particular even over 90 wt. %.

In principle, the at least one alcohol of the composite composition can comprise methanol and/or the at least one silanol of the composite composition can in principle be prepared by converting at least one trimethoxysilane with water by splitting off methanol.

However, ethanol and/or propanol, for example isopropanol and/or n-propanol, and/or butanol, for example tert-butanol and/or sec-butanol and/or isobutanol and/or n-butanol, have the advantages over methanol of lower toxicity and a higher boiling point, which has proven to be advantageous in particular with regard to the processing and handling of the composite composition.

For example, the at least one alcohol can therefore comprise or be ethanol and/or propanol, for example isopropanol and/or n-propanol, and/or butanol, for example tert-butanol, sec-butanol and/or isobutanol and/or n-butanol, for example ethanol and/or propanol, for example isopropanol and/or n-propanol, and/or the at least one trialkoxysilane can comprise or be at least one triethoxysilan and/or tripropoxysilane and/or tributoxysilane, for example a triethoxysilane and/or tripropoxysilane.

Ethanol has proven to be particularly advantageous, since it has a low toxicity, is inexpensive, and also forms an azeotrope with water, which also makes it possible to remove even low water fractions in a simple and energy-efficient manner during drying of the composite composition.

In particular, therefore, the at least one alcohol can comprise or be ethanol and/or the at least one trialkoxysilane can comprise or be at least one triethoxysilane.

In a further embodiment of the present invention, the composite composition further comprises, relative to the total weight of the composite composition, ≥1 wt. % to ≤15 wt. % of the at least one alcohol. For example, the composite composition can comprise, relative to the total weight of the composite composition, ≥2 wt. % to ≤12 wt. %, for example ≥3 wt. % to ≥11 wt. %, in particular ≥5 wt. % to ≤10 wt. %, of the at least one alcohol. This has proven to be advantageous in the context of the present invention. For example, the composite composition can therefore comprise, based on the total weight of the composite composition, ≥1 wt. % to ≤15 wt. %, for example ≥2 wt. % to ≤12 wt. %, for example ≥3 wt. % to ≤11 wt. %, in particular ≥5 wt. % to ≤10 wt. %, of, in particular in total, methanol and/or ethanol and/or propanol, for example isopropanol and/or n-propanol, and/or butanol, for example tert-butanol and/or sec-butanol and/or isobutanol and/or n-butanol. In particular, the composite composition can comprise, based on the total weight of the composite composition, ≥1 wt. % to ≤15 wt. %, for example ≥2 wt. % to ≤12 wt. %, for example ≥3 wt. % to ≤11 wt. %, in particular ≥5 wt. % to ≤10 wt. %, of ethanol.

Furthermore, the composite composition can comprise, for example, at least one silicone resin and/or at least one wetting agent and/or at least one defoamer.

A wetting agent can in particular be understood to mean an additive that can contribute to improved wetting of the composite composition on a metallic and/or ceramic substrate and of liquid components of the composite composition on the filler surfaces.

In a further embodiment of the present invention, the composite composition further comprises, relative to the total weight of the composite composition,
≥0 wt. % to ≤10 wt. % of the at least one, in particular crosslinkable, polysiloxane resin or silicone resin, and/or
≥0 wt. % to ≤2.5 wt. % of the at least one wetting agent, and/or ≥0 wt. % to ≤0.2 wt. % of the at least one defoamer.

By adding at least one polysiloxane resin, further properties of the composite composition and/or of the composite formed therefrom can advantageously be adjusted, for example the water absorption can be reduced and/or the modulus of elasticity and/or the thermal expansion can be adapted.

The at least one wetting agent can, for example, comprise and/or be based on and/or be at least one polycarboxylate ether.

If the at least one polysiloxane resin and/or the at least one wetting agent contains water or is added in the form of an aqueous solution/suspension/dispersion to the composite composition, it is advantageous to ensure that the total water content of the composite composition remains below 10 wt. %.

In particular, the at least one silicone resin and/or the at least one wetting agent and/or the at least one defoamer can therefore be low in water, preferably anhydrous.

With regard to further technical features and advantages of the composite composition according to the present invention, explicit reference is hereby made to the explanations in connection with the silanol composition production method according to the present invention, the silanol composition according to the present invention, the composite composition production method according to the present invention, the composite and/or structure production method according to the present invention, the composite according to the present invention, and/or the solid structure according to the present invention, and the use according to the present invention, as well as to the FIGURE, the FIGURE description, and the exemplary embodiments.

A further subject of the present invention is a method for producing a silanol composition, in particular for a composite composition, in which, in particular in a closed system, in particular at a temperature of ≥60° C., for example of ≥70° C., in particular at a temperature in a range of ≥60° C., for example ≥70° C., in particular up to ≤100° C., a mixture of at least one trialkoxysilane and water is converted to form at least one silanol and at least one alcohol.

In particular, the alkoxy groups of the at least one trialkoxysilane can be hydrolyzed by the water, forming hydroxyl groups (instead of the alkoxy group) on the silicon atom of the silane, and thus forming the at least one silanol, in particular the at least one silanetriol, and forming the at least one alcohol. Due to the formation of the hydroxyl groups, the formed silanol advantageously becomes soluble, in particular not only in water, but also in particular in the alcohol forming from hydrolyzed alkoxy groups of the trialkoxysilane, which makes it possible to use the formed, alcohol-dissolved silanol directly in the form of the formed alcoholic solution in the composite composition.

In one embodiment of the present invention, the mixture is converted in a closed system. It can thus advantageously be brought about that the alcohol that forms and also the water required for the reaction remain in the mixture, in particular until the complete conversion of the water.

In particular, the mixing can take place at a particular temperature and/or for a particular period of time.

In a further embodiment, the conversion takes place at a temperature of ≥60° C., for example ≥70° C., in particular up to ≤100° C. The hydrolysis reaction can advantageously be accelerated by a temperature of ≥60° C., for example of ≥70° C. By limiting the temperature to below 100° C., premature condensation reactions can advantageously be avoided.

The closed system can, for example, also be designed to be pressure-resistant and/or as an autoclave. The temperature can thus advantageously also be adjusted to above the boiling point of the alcohol to be formed.

The particular time for which the mixture is mixed can in particular be based on the selected temperature. When converting at a temperature of 70° C., the mixture can already become clear after 45 minutes, which basically indicates the formation of silanols, but in order to form silanetriols, the mixture is preferably mixed at 70° C. for at least 3 hours, for example up to one day. At higher temperatures, the time required for mixing is shortened according to the applied temperature.

In a further embodiment of the present invention, the mixture used comprises, relative to the total weight of the mixture,
≥70 wt. % to ≤90 wt. %, in particular ≥75 wt. % to ≤90 wt. %, for example ≥76 wt. % to ≤85 wt. %, of the at least one trialkoxysilane, and
≥10 wt. % to ≤30 wt. %, for example ≥10 wt. % to ≤25 wt. %, in particular ≥15 wt. % to ≤24 wt. %, of water. In particular, the percentage by weight of the at least one trialkoxysilane and the percentage by weight of water in the mixture can add up to 100% by weight.

By minimizing the amount of water used in the mixture, it can advantageously be achieved that the silanol composition produced therefrom further contains only a low or possibly even no significant amount of water, which can have an advantageous effect in the composite composition, as already explained.

In order to minimize the water content of the silanol composition, an amount of water by which at least a large part of the alkoxy groups, in particular all the alkoxy groups, of the at least one trialkoxysilane are converted to hydroxyl groups of the at least one silanol, in particular silanetriol, and/or which is completely converted to hydroxyl groups of the at least one silanol, in particular silanetriol, is preferably used in the mixture.

This can be achieved in particular by using the water in a stoichiometric amount or at most in a slightly overstoichiometric amount, for example by a factor of ≤1.7, for example ≤1.5, in particular ≤1.3, for example ≤1.1, but preferably in a stoichiometric amount, in particular with a factor of 1, to the alkoxy groups of the at least one trialkoxysilane.

By using the water in such an amount to the alkoxy groups of the at least one trialkoxysilane, the at least one silanol, in particular the at least one silanetriol, can advantageously be used in the form of a low-water, optionally almost anhydrous, alcoholic solution in the composite composition, which has proven to be particularly advantageous for the processing and/or for the faster and more energy-saving curing of the composite composition.

The at least one trialkoxysilane can, for example, comprise or be at least one trimethoxysilane and/or at least one triethoxysilane and/or at least one tripropoxysilane and/or at least one tributoxysilane. For example, the at least one alcohol can comprise or be methanol and/or ethanol and/or propanol, for example isopropanol and/or n-propanol, and/or butanol, for example tert-butanol and/or sec-butanol and/or isobutanol and/or n-butanol.

In a further embodiment of the present invention, the at least one trialkoxysilane comprises or is at least one triethoxysilane and/or at least one tripropoxysilane and/or at least one tributoxysilane. For example, the at least one alcohol can in particular comprise or be ethanol and/or propanol, for example isopropanol and/or n-propanol, and/or butanol, for example tert-butanol and/or sec-butanol and/or isobutanol and/or n-butanol. These trialkoxysilanes have proven to be advantageous with regard to low toxicity and good processability of the alcohol formed therefrom in the composite composition.

For example, the at least one trialkoxysilane can comprise or be at least one triethoxysilane and/or at least one tripropoxysilane. The at least one alcohol can in particular comprise or be ethanol and/or propanol, for example isopropanol and/or n-propanol. In particular, the at least one trialkoxysilane can comprise or be at least one triethoxysilane. The at least one alcohol can in particular comprise or be ethanol. These trialkoxysilanes have proven to be advantageous with regard to low toxicity, good processability of the alcohol formed therefrom in the composite composition and low production costs.

In a further embodiment of the present invention, the at least one trialkoxysilane comprises an organic moiety, for example with a chain length of ≥1 atom, for example with a chain length of ≥2 atoms or ≥3 atoms, for example with a chain length of ≥ 4 or ≥5 or ≥6 atoms, for example with a chain length of ≥7 atoms, and/or with at least one functional group, for example with at least one epoxy group and/or amino group and/or mercapto group and/or vinyl group, in particular epoxy group.

For example, the at least one trialkoxysilane can comprise or be at least one trialkoxyepoxysilane, for example at least one trimethoxyepoxysilane and/or at least one triethoxyepoxysilane and/or at least one tripropoxyepoxysilane and/or at least one tributoxyepoxysilane, for example at least one triethoxyepoxysilane and/or at least one tripropoxyepoxysilane and/or at least one tributoxyepoxysilane, for example at least one triethoxyepoxysilane and/or at least one tripropoxyepoxysilane, in particular at least one triethoxyepoxysilane, and/or at least one trialkoxyaminosilane, for example at least one trimethoxyaminosilane and/or at least one triethoxyaminosilane and/or at least one tripropoxyaminosilane and/or at least one tributoxyaminosilane, for example at least one triethoxyaminosilane and/or at least one tripropoxyaminosilane and/or at least one tributoxyaminosilane, for example at least one triethoxyaminosilane and/or at least one tripropoxyaminosilane, in particular at least one triethoxyaminosilane, and/or at least one trialkoxymercaptosilane, for example at least one trimethoxymercaptosilane and/or at least one triethoxymercaptosilane and/or at least one tripropoxymercaptosilane and/or at least one tributoxymercaptosilane, for example at least one triethoxymercaptosilane and/or at least one tripropoxymercaptosilane and/or at least one tributoxymercaptosilane, for example at least one triethoxymercaptosilane and/or at least one tripropoxymercaptosilane, in particular at least one triethoxymercaptosilane, and/or at least one trialkoxyvinylsilane, for example at least one trimethoxyvinylsilane and/or at least one triethoxyvinylsilane and/or at least one tripropoxyvinylsilane and/or at least one tributoxyvinylsilane, for example at least one triethoxyvinylsilane and/or at least one tripropoxyvinylsilane and/or at least one tributoxyvinylsilane, for example at least one triethoxyvinylsilane and/or at least one tripropoxyvinylsilane, in particular at least one triethoxyvinylsilane.

For example, the at least one trialkoxysilane can comprise or be (3-glycidyloxypropyl)triethoxysilane (GLYEO).

As a result of its production, the silanol composition thus produced can have a high alcohol fraction and can advantageously be used both for the provision of the at least one silanol in the composite composition according to the present invention and/or as a composite composition additive, and, as such, as a casting compound for application on a, in particular metallic and/or ceramic, material, and/or with at least one, in particular ceramic and/or metallic, filler. For example, the silanol composition can also be used as such for coating and/or for potting a, in particular metallic and/or ceramic, material, and/or at least one, in particular ceramic and/or metallic, filler.

For example, a silanol composition prepared from the amounts of trialkoxysilane and water indicated above can comprise, based on the total weight of the silanol composition,
≥30 wt. % to ≤70 wt. %, for example ≥35 wt. % to ≤65 wt. %, in particular ≥40 wt. % to ≤60 wt. %, of at least one silanol, ≥25 wt. % to ≤70 wt. %, for example ≥30 wt. % to ≤65 wt. %, in particular ≥40 wt. % to ≤60 wt. %, of at least one alcohol, for example, in particular in total, of methanol and/or ethanol and/or propanol, for example isopropanol and/or n-propanol, and/or butanol, for example tert-butanol, sec-butanol and/or isobutanol and/or n-butanol, and
≥0 wt. % to ≤20 wt. %, for example ≥0 wt. % to ≤15 wt. % or ≤10 wt. %, in particular ≥0 wt. % to ≤5 wt. %, of water.

In particular, the percentage by weight of the at least one silanol, the percentage by weight of the at least one alcohol and the percentage by weight of water can in total yield 100 percent by weight, or the silanol composition can consist of ≥30 wt. % to ≤70 wt. %, for example ≥35 wt. % to ≤65 wt. %, in particular ≥40 wt. % to ≤60 wt. %, of at least one silanol, ≥25 wt. % to ≤70 wt. %, for example ≥30 wt. % to ≤65 wt. %, in particular ≥40 wt. % to ≤60 wt. %, of at least one alcohol, and ≥0 wt. % to ≤20 wt. %, for example ≥0 wt. % to ≤15 wt. % or ≤10 wt. %, in particular ≥0 wt. % to ≤5 wt. %, of water, based on the total weight of the silanol composition.

For use in a composite composition according to the present invention, the alcohol that forms is preferably not removed from the mixture or remains in the mixture. It is also preferable not to add any (additional) water.

However, by partially or completely distilling off the at least one alcohol, the proportion of the at least one silanol in the silanol composition can, if necessary, be increased and the proportion of the at least one alcohol can be reduced. Advantageously, the proportion of water can also be further reduced in the process. This can advantageously be carried out particularly effectively in a synthesis from triethoxysilanes, since ethanol can be distilled off as an azeotrope with water in a particularly effective, simple, and energy-saving manner. Preferably, no (further) water is added in this embodiment as well, for example after the partial or complete, in particular partial, distilling off of the at least one alcohol.

With regard to further technical features and advantages of the silanol composition production method according to the present invention, explicit reference is hereby made to the explanations in connection with the composite composition according to the present invention, the silanol composition according to the present invention, the composite composition production method according to the present invention, the composite and/or structure production method according to the present invention, the composite according to the present invention, and/or the solid structure according to the present invention, and the use according to the present invention, as well as to the FIGURE, the description of the FIGURE, and the exemplary embodiments of the present invention.

A further subject of the present invention is a silanol composition which comprises, based on the total weight of the silanol composition, ≥30 wt. % to ≤70 wt. %, for example ≥35 wt. % to ≤65 wt. %, in particular ≥40 wt. % to ≤60 wt. %, of at least one silanol, ≥25 wt. % to ≤70 wt. %, for example ≥30 wt. % to ≤65 wt. %, in particular ≥40 wt. % to ≤60 wt. %, of at least one alcohol, and ≥0 wt. % to ≤20 wt. %, for example ≥0 wt. % to ≤15 wt. % or ≤10 wt. %, in particular ≥0 wt. % to ≤5 wt. %, of water.

In particular, the percentage by weight of the at least one silanol, the percentage by weight of the at least one alcohol and the percentage by weight of water can in total yield 100 percent by weight, or the silanol composition can consist of ≥30 wt. % to ≤70 wt. %, for example ≥35 wt. % to ≤65 wt. %, in particular ≥40 wt. % to ≤60 wt. %, of at least one silanol, ≥25 wt. % to ≤70 wt. %, for example ≥30 wt. % to ≤65 wt. %, in particular ≥40 wt. % to ≤60 wt. %, of at least one alcohol, and ≥0 wt. % to ≤20 wt. %, for example ≥0 wt. % to ≤15 wt. % or ≤10 wt. %, in particular ≥0 wt. % to ≤5 wt. %, of water, based on the total weight of the silanol composition.

The silanol composition can in particular be flowable and/or pourable. The silanol composition can therefore be used in particular, for example as a casting compound, for coating and/or for casting and/or for potting. The silanol composition can particularly advantageously be used for application with at least one, in particular ceramic and/or metallic, filler and/or on a, in particular metallic and/or ceramic, material. In particular, the silanol composition can be used for producing a composite composition according to the present invention and/or can be produced by a method according to the present invention for producing a silanol composition. For example, the silanol composition can also be used as such for coating and/or for potting a, in particular metallic and/or ceramic, material, and/or at least one, in particular ceramic and/or metallic, filler.

The silanol composition can, for example, be cured at a temperature in a range of ≥130° C. to ≤250° C. The silanol composition is preferably dried before curing, in particular in order to remove the at least one alcohol and optionally water.

For example, the at least one alcohol can in principle comprise or be methanol and/or ethanol and/or propanol, for example isopropanol and/or n-propanol, and/or butanol, for example tert-butanol, sec-butanol and/or isobutanol and/or n-butanol. In particular, the at least one alcohol can comprise or be ethanol and/or propanol, for example isopropanol and/or n-propanol, and/or butanol, for example tert-butanol, sec-butanol and/or isobutanol and/or n-butanol. For example, the at least one alcohol can comprise or be ethanol and/or propanol, for example isopropanol and/or n-propanol.

In one embodiment of the present invention, the at least one alcohol is ethanol.

In a further embodiment of the present invention, the at least one silanol comprises or is at least one silanetriol.

In a further embodiment of the present invention, the at least one silanol comprises an organic moiety, for example with a chain length of ≥1 atom, for example with a chain length of ≥2 atoms or ≥3 atoms, for example with a chain length of ≥4 or ≥5 or ≥6 atoms, for example with a chain length of ≥7 atoms, and/or with at least one functional group, for example with at least one epoxy group and/or amino group and/or mercapto group and/or vinyl group, in particular epoxy group.

For example, the at least one silanol can comprise or be at least one epoxysilanetriol or epoxytrihydroxysilane and/or at least one aminosilanetriol or aminotrihydroxysilane and/or at least one mercaptosilanetriol or trihydroxymercaptosilane and/or at least one vinylsilanetriol or trihydroxyvinylsilane.

For example, the at least one silanol, in particular silanetriol, can comprise or be (3-glycidyloxypropyl) silanetriol or (3-glycidyloxypropyl)trihydroxysilane.

With regard to further technical features and advantages of the silanol composition according to the present invention, explicit reference is hereby made to the explanations in connection with the composite composition according to the present invention, the silanol composition production method according to the present invention, the composite composition production method according to the present invention, the composite and/or structure production method according to the present invention, the composite according to the present invention, and/or the solid structure according to the present invention, and the use according to the present invention, as well as to the FIGURE, the FIGURE description and the exemplary embodiments.

The present invention also relates to a method for preparing a composite composition according to the present invention. In particular, at least one silanol and at least one filler can be mixed in the method. In this case, relative to the total weight of the composite composition to be produced, ≥10 wt. % to ≤95 wt. % of the at least one filler and ≥1 wt. % to ≤15 wt. % of the at least one silanol can be used.

For example, based on the total weight of the composite composition to be produced, ≥15 wt. % or ≥20 wt. % or ≥25 wt. % or ≥30 wt. % or ≥35 wt. % or ≥40 wt. % or ≥45 wt. % or ≥50 wt. or ≥55 wt. %, in particular ≥60 wt. %, for example ≥61 wt. % or ≥62 wt. % or ≥63 wt. % or ≥64 wt. % or ≥65 wt. % or ≥66 wt. % or ≥67 wt. % or ≥68 wt. % or ≥69 wt. %, for example ≥70 wt. % or ≥71 wt. % or ≥72 wt. % or ≥73 wt. % or ≥74 wt. %, for example ≥75 wt. % or ≥76 wt. % or ≥77 wt. % or ≥78 wt. % or ≥79 wt. %, for example ≥80 wt. % or ≥81 wt. % or ≥82 wt. % or ≥83 wt. % or ≥84 wt. %, for example ≥85 wt. % or ≥86 wt. % or ≥87 wt. %, for example ≥88 wt. %, to ≤95 wt. %, for example to ≤94 wt. % or ≤93 wt. %, for example to ≤92 wt. %, of the at least one filler and ≥1 wt. % to ≤15 wt. %, for example ≥2 wt. % to ≤12 wt. %, for example ≥3 wt. % to ≤11 wt. %, for example ≥5 wt. % to ≤10 wt. %, of the at least one silanol can be used.

Advantageously, the composite composition prepared in this way can be storable until processing, in particular with rotation (to prevent settling of the coarse particles), for at least one day, possibly also for more than a week.

In one embodiment of the present invention, at least one alcohol is also added to the mixture. Here, in particular ≥1 wt. % to ≤15 wt. %, for example ≥2 wt. % to ≤12 wt. %, for example ≥3 wt. % to ≤11 wt. %, for example ≥5 wt. % to ≤10 wt. %, of the at least one alcohol, based on the total weight of the composite composition to be produced, can be used. The flowability of the composite composition to be prepared can thus advantageously be adjusted.

In a further embodiment of the present invention, the at least one silanol and/or the at least one alcohol, in particular the at least one silanol and the at least one alcohol, are used in the form of an alcoholic solution. In particular, the at least one filler can be added to the alcoholic solution of the at least one silanol. The at least one silanol and the at least one filler can thus advantageously be homogenized in a simple manner.

In a further embodiment of the present invention, the at least one silanol and/or the at least one alcohol, in particular the at least one silanol and the at least one alcohol, is/are used in the form of a silanol composition prepared by a method according to the present invention and/or in the form of a silanol composition according to the present invention. This has proven to be particularly advantageous for the production of the composite composition.

In a further embodiment of the present invention, the mixing, in particular by stirring, takes place under a, for example moderate, vacuum, for example of 80 mbar (absolute).

The composite composition can thus advantageously be degassed or deaerated and at the same time even solvents, for example the at least one alcohol and optionally water, can be at least partially removed, as a result of which, on the one hand, holes in the composite to be formed can be avoided and, on the other hand, drying can also be accelerated after application of the composite composition and in particular before curing of the composite composition.

With regard to further technical features and advantages of the composite composition production method according to the present invention, explicit reference is hereby made to the explanations in connection with the composite composition according to the present invention, the silanol composition production method according to the present invention, the silanol composition according to the present invention, the composite and/or structure production method according to the present invention, the composite according to the present invention, and/or the solid structure according to the present invention, and the use according to the present invention, as well as to the FIGURE, the description of the FIGURE, and the exemplary embodiments.

A further subject of the present invention is a method for producing a composite and/or a solid structure, for example in the form of a, in particular cured, potting and/or a, in particular cured, casting and/or a, in particular cured, coating, in which a composite composition according to the present invention and/or a silanol composition produced according to a method according to the present invention and/or a silanol composition according to the present invention and/or a composite composition produced according to a method according to the present invention is cured at a temperature in a range of ≥130° C., for example up to ≤250° C.

As already explained in detail, strong chemical bonds can thus be formed via condensation reactions of the at least one silanol by splitting off water, thereby forming a very stable composite that adheres in particular well to metallic and/or ceramic surfaces or a very stable solid structure that, for example, adheres well to metallic and/or ceramic surfaces, with the additional advantages explained above.

In particular, the composite composition and/or the silanol composition can first be poured, for example to form a casting and/or a potting and/or a coating, and then cured. Pouring can, for example, take place by means of a dispenser.

In principle, free shapes, in particular without a substrate, can also advantageously be cast by the method.

In one embodiment of the present invention, however, the composite composition and/or the silanol composition is first poured onto a, in particular ceramic and/or metallic, substrate, and is then cured.

The composite composition and the silanol composition can advantageously already adsorb onto surfaces of substrates at room temperature and form strong chemical bonds at the curing temperature and thus a strong adhesion to the, for example metallic and/or ceramic, surface of the substrate.

In a further embodiment of the present invention, the composite composition and/or the silanol composition is dried before curing, in particular after pouring and before curing. The drying can take place, for example, at a temperature in a range of ≥25° C. to ≤95° C. Optionally, the drying can take place under vacuum and/or chemically water-binding substances.

In this way, solvents, for example the at least one alcohol and optionally water, can advantageously be removed partially or completely. An associated minimal volume shrinkage of the compound can occur at the height of the potting level, but since the compound still has plastic behavior due to the liquid silanol content, no stresses are produced thereby. Due to the fact that this is brought about moderately during the drying, stresses and cracking can be minimized during subsequent curing at higher temperatures.

In a further embodiment of the present invention, the substrate comprises or is at least one electronic and/or electrical component and/or at least one electronic and/or electrical assembly, for example at least one chip, for example at least one silicon and/or silicon carbide and/or gallium nitride chip, in particular at least one electronic module, such as a frame module, and/or at least one printed circuit board, for example a ceramic printed circuit board, for example on the basis of aluminum oxide and/or with at least one aluminum and/or copper layer, for example DBC (direct bonded copper), AMB (active metal brazed), LTCC (low-temperature co-fired ceramic), et cetera, and/or a metallic printed circuit board, for example a circuit board, and/or at least one wire, for example at least one bonding wire and/or at least one coil winding, and/or at least one solder, for example tin solder.

Advantageously, the composite composition and/or the silanol composition can be so flowable that they can distribute themselves even between such small structures under the influence of gravity and the displacement of air. In particular, the composite composition can be used particularly advantageously for potting such substrates due to the numerous advantages described above.

With regard to further technical features and advantages of the composite and/or structure production method according to the present invention, explicit reference is hereby made to the explanations in connection with the composite composition according to the present invention, the silanol composition production method according to the present invention, the silanol composition according to the present invention, the composite composition production method according to the present invention, the composite according to the present invention, and/or the solid structure according to the present invention, and the use according to the present invention, as well as to the FIGURE, the description of the FIGURE, and the exemplary embodiments.

A further subject of the present invention is a composite, for example an electronics and/or electrics composite, in particular a power electronics composite, for example an electronics and/or electrics composite potting, in particular a power electronics composite potting, and/or a solid structure, for example in the form of a, in particular cured, potting and/or a, in particular cured, casting and/or a, in particular cured, coating, which is produced by a method according to the present invention.

Composites and/or solid structures according to the present invention can advantageously be detected by means of elemental analysis, FTIR spectroscopy, and/or other methods characterizing the bonding structure and/or by means of SEM analysis and/or other methods representing the microstructure and/or by means of EDX analysis and/or other methods identifying the binder phase in addition to fillers.

With regard to further technical features and advantages of the composite according to the present invention, and/or the solid structure according to the present invention, explicit reference is hereby made to the explanations in connection with the composite composition according to the present invention, the silanol composition production method according to the present invention, the silanol composition according to the present invention, the composite composition production method according to the present invention, the composite and/or structure production method according to the present invention, and the use according to the present invention, as well as to the FIGURE, the description of the FIGURE, and the exemplary embodiments.

The present invention further relates to the use of a composite composition according to the present invention and/or a silanol composition produced according to the present invention and/or a silanol composition according to the present invention and/or a composite composition produced according to the present invention as a potting compound and/or casting compound and/or coating agent, for example for electrics and/or electronics, in particular power electronics.

In this way, conventional potting compounds and/or casting compounds and/or coating agents, for example agents conventionally used in electronics and/or electrics, such as conventional potting compounds and/or casting compounds and/or silicone gels and/or so-called conformal coatings (printed circuit board lacquer/insulating lacquer) and/or other coating agents, can advantageously be replaced through the use of the composite composition and/or silanol composition according to the present invention.

The composite composition and/or silanol composition according to the present invention can advantageously also be applied directly and/or to uninsulated electronic and/or electrical components, for example modules, for example uninsulated power electronics, for example so-called bare dies (unpackaged semiconductor chips), for example which are mounted on a printed circuit board, for example on a ceramic printed circuit board or on an organically bonded printed circuit board or a so-called leadframe (printed circuit board leadframe). The composite composition and/or silanol composition can advantageously be used for application both on active electronic modules and on passive electronic modules.

The composite composition can advantageously be used for potting voluminous components and assemblies as well as flat components and assemblies. In addition, the composite composition can of course also be used for potting insulated electronic and/or electrical components, for example the winding of a choke coil, for example an EMC choke coil, and/or already encased packages. The composite composition can particularly advantageously be used for potting power electronics, in particular power electronics under high thermal loading, for example for high voltages and/or currents. The composite composition can also advantageously be used for potting other types of electronics, for example for control electronics.

With regard to further technical features and advantages of the use according to the present invention, reference is hereby explicitly made to the explanations in connection with the composite composition according to the present invention, the silanol composition production method according to the present invention, the silanol composition according to the present invention, the composite composition production method according to the present invention, the composite and/or structural production method according to the present invention, and the composite according to the present invention, and/or the solid structure according to the present invention, and to the FIGURE, the description of the FIGURE, and the exemplary embodiment of the present invention.

### BRIEF DESCRIPTION OF THE DRAWINGS

Further advantages and advantageous embodiments of the subjects according to the present invention are illustrated by the FIGURE and the exemplary embodiments and explained in the following description. It should be noted that the FIGURE and the exemplary embodiments are only descriptive in character and are not intended to limit the present invention in any way.

FIG. 1 is a schematic cross-section through an example embodiment of an electronics composite potting according to the present invention.

### DETAILED DESCRIPTION OF EXAMPLE EMBODIMENTS

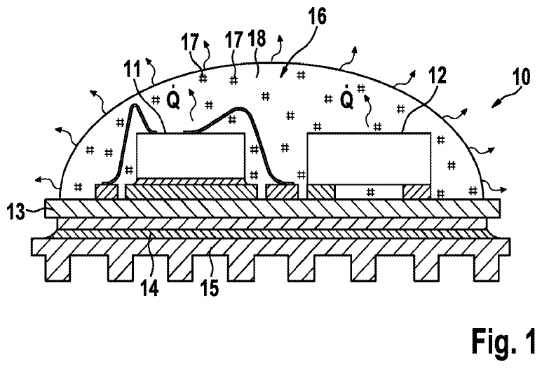

FIG. 1 shows an electronics composite potting 10, which comprises an active component 11 in the form of a semiconductor chip, for example on the basis of silicon and/or silicon carbide and/or silicon nitride, with bonding wires and a passive component 12, for example a capacitor. The two components 11, 12 are arranged on a ceramic printed circuit board 13, for example DCB, AMB, et cetera, which 13 in turn is arranged on a heat conducting paste 14 applied to a cooler 15.

FIG. 1 shows that the components 11, 12 and their periphery, such as the bonding wires, and the upper side of the printed circuit board 13 are potted with a composite potting 16, which comprises filler particles 17. In this case, the surfaces of the filler particles 17 are connected via chemical bonds (not shown) to a three-dimensional Si—O—Si—O network 18, wherein the three-dimensional Si—O—Si—O-network 18 in turn is connected via chemical bonds (not shown) to the surface of the components 11, 12, to the periphery thereof, and to the upper side of the printed circuit board 13. Such a composite potting 16 or electronic composite potting can advantageously be produced from a composite composition according to the present invention which comprises ≥10 wt. % to ≤95 wt. %, in particular ≥60 wt. % to ≤95 wt. %, of at least one filler and ≥1 wt. % to ≤15 wt. %, in particular ≥2 wt. % to ≤12 wt. %, of at least one silanol, and by means of a production method according to the present invention.

FIG. 1 shows that the composite composition according to the present invention can be so flowable that it can distribute itself even between such small structures without pressure under the influence of gravity and the displacement of air.

The curved arrows in FIG. 1 indicate that a good thermal conductivity and thereby a temperature spreading and temperature dissipation in the volume can thus be ensured.

### EXEMPLARY EMBODIMENTS

In the following exemplary embodiments 1 to 4, different composite compositions were prepared by mixing the components and amounts indicated in Tables 1 to 4.

Tables 1 to 4 show that at least one aluminum oxide filler and at least one silanol were used in the embodiments. In addition, all compositions contained a water-dissolved liquefier and a defoamer.

### Exemplary Embodiment 1

TABLE 1
Exemplary embodiment with coarse aluminum oxide filler
particles, commercially available, water-dissolved
silanol and addition of water

| | Weight |
|---|---|
| Material | [wt. % ] |
| High-purity Al₂O₃ “coarse” | 90.84 |
| (d₅₀ = 10-40 μm, dₘₐₓ = 70-110 μm) | |
| Silanol (water-dissolved) | 2.76 |
| Liquefier (water-dissolved) | 0.78 |
| Defoamer | 0.08 |
| Water | 5.55 |

In the exemplary embodiments 1, a coarse aluminum oxide filler and a commercially available, water-dissolved silanol and additional water were used.

### Exemplary Embodiment 2

TABLE 2
Exemplary embodiment with coarse and fine aluminum
oxide filler particles and commercially available,
water-dissolved silanol and water-emulsified
polysiloxane resin without addition of water

| | Weight |
|---|---|
| Material | [wt. % ] |
| High-purity Al₂O₃ “coarse” | 88.51 |
| (d₅₀ = 10-40 μm, dₘₐₓ = 70-110 μm) | |
| High-purity Al₂O₃ “fine” | 4.91 |
| (d₅₀ = 0.1-0.2 μm) | |
| Silanol (water-dissolved) | 7.54 |
| Polysiloxane resin (water-emulsified) | 3.07 |
| Liquefier (water-dissolved) | 0.81 |
| Defoamer | 0.08 |
| Water | 0.00 |

In the exemplary embodiments 2, a coarse and a fine aluminum oxide filler, commercially available, water-dissolved silanol, and a water-emulsified polysiloxane resin were used, and no water was added.

### Exemplary Embodiment 3

TABLE 3
Exemplary embodiment with coarse and fine
aluminum oxide filler particles and an alcoholic
silanol composition prepared by hydrolysis of (3-
glycidyloxypropyl) triethoxysilane,
without addition of water

| | Weight |
|---|---|
| Material | [wt. %] |
| High-purity Al₂O₃ “coarse” | 84.30 |
| (d₅₀ = 10-40 μm, dₘₐₓ = 70-110 μm) | |
| High-purity Al₂O₃ “fine” | 4.95 |
| (d₅₀ = 0.1-0.2 μm) | |
| Silane composition prepared from (3- | 9.85 |
| glycidyloxypropyl) silanol and ethanol | |
| Liquefier (water-dissolved) | 0.82 |
| Defoamer | 0.08 |
| Water | 0.00 |

In the exemplary embodiments 3, a coarse and a fine aluminum oxide filler and a self-produced silanol composition were used, and no water was added. The silanol composition was prepared by stirring a mixture of (3-glycidyloxypropyl)triethoxysilane with a stoichiometric amount of water with respect to the ethoxy groups at 70° C. for 3 hours in a closed system and converting the mixture to form (3-glycidyloxypropyl) silanol and ethanol.

### Exemplary Embodiment 4

TABLE 4
Exemplary embodiment with coarse and fine
aluminum oxide filler particles and an alcoholic
silanol composition prepared by hydrolysis of (3-
glycidyloxypropyl) triethoxysilane and 3-
mercaptopropyltriethoxysilane, without addition of
water

| | Weight |
|---|---|
| Material | [wt. % ] |
| High-purity Al₂O₃ “coarse” | 84.30 |
| (d₅₀ = 10-40 μm, dₘₐₓ = 70-110 μm) | |
| High-purity Al₂O₃ “fine” | 4.95 |
| (d₅₀ = 0.1-0.2 μm) | |
| Silane composition prepared from (3- | 9.85 |
| glycidyloxypropyl) silanol, 3- | |
| mercaptopropyltriethoxysilane and | |
| ethanol | |
| Liquefier (water-dissolved) | 0.82 |
| Defoamer | 0.08 |
| Water | 0.00 |

In the exemplary embodiments 4, a coarse and a fine aluminum oxide filler and a self-produced silanol composition were used, and no water was added. The silanol composition was prepared by stirring a mixture of (3-glycidyloxypropyl)triethoxysilane and 3-mercaptopropyltriethoxysilane with a stoichiometric amount of water with respect to the ethoxy groups at 70° C. for 3 hours in a closed system and converting the mixture to form (3-glycidyloxypropyl) silanol and 3-mercaptopropylsilanol and ethanol.

It can be seen that the composite compositions according to the exemplary embodiments 1 to 4 were suitable for potting electronics and/or electrics. The composite compositions of exemplary embodiments 3 and 4 with the self-produced, in particular low-water or almost anhydrous, silanol compositions were distinguished as particularly advantageous due to reduced hole formation, faster curing, a thermal conductivity of over 6 W/(m·K) and an adhesive strength to Cu of over 8 MPa.

1-30. (canceled)

31. A composite composition for forming a composite for potting electronics and/or electrics, wherein the composite composition comprises, relative to a total weight of the composite composition,
≥10 wt. % to ≤95 wt. % of at least one filler, and
≥1 wt. % to ≤15 wt. % of at least one silanol.

32. The composite composition according to claim 31, wherein the composite composition comprises <10 wt. % of water, relative to the total weight of the composite composition.

33. The composite composition according to claim 31, wherein the at least one filler includes at least one ceramic filler and/or metallic filler.

34. The composite composition according to claim 31, wherein the at least one filler includes at least one oxidic filler and/or nitridic filler and/or carbidic filler and/or siliceous filler.

35. The composite composition according to claim 31, wherein the at least one filler includes aluminum oxide and/or silicon oxide and/or magnesium oxide and/or zirconium oxide and/or forsterite and/or aluminum nitride and/or boron nitride and/or silicon nitride.

36. The composite composition according to claim 31, wherein the composite composition comprises, relative to the total weight of the composite composition,
≥60 wt. % to ≤95 wt. % of the at least one filler, and/or
≥2 wt. % to ≤12 wt. % of the at least one silanol.

37. The composite composition according to claim 31, wherein the at least one filler includes at least one coarse filler and at least one fine filler.

38. The composite composition according to claim 37, wherein: (i) the at least one coarse filler has a granulation band in a range of ≥1 μm to ≤200 μm and/or a D50 value of ≥5 μm to ≤110 μm, and (ii) the at least one fine filler has a granulation band in a range of ≥0.05 μm to ≤1 μm and/or a D50 value of ≥0.1 μm to ≤0.9 μm.

39. The composite composition according to claim 37, wherein the composite composition comprises, relative to the total weight of the composite composition,
≥60 wt. % to ≤90 wt. % of the at least one coarse filler, and
≥0 wt. % to ≤8 wt. % of the at least one fine filler.

40. The composite composition according to claim 31, wherein the at least one silanol includes at least one silanetriol.

41. The composite composition according to claim 31, wherein the at least one silanol, comprises an organic moiety, and the organic moiety includes at least one functional group including an epoxy group and/or an amino group and/or a mercapto group and/or a vinyl group.

42. The composite composition according to claim 31, wherein the composite composition, relative to the total weight of the composite composition, further comprises ≥1 wt. % to ≤15 wt. % of at least one alcohol.

43. The composite composition according to claim 42, wherein the at least one silanol and/or the at least one alcohol is contained in the form of a silanol composition in the composite composition, wherein the silanol composition includes at least one silanol and at least one alcohol, wherein the silanol composition is produced by converting a mixture of at least one trialkoxysilane and water.

44. A method for producing a silanol composition for a composite composition, the composite composition including, relative to a total weight of the composite composition, ≥10 wt. % to ≤95 wt. % of at least one filler, and ≥1 wt. % to ≤15 wt. % of at least one silanol, the method comprising:
converting a mixture of at least one trialkoxysilane and water in a closed system at a temperature of ≥60° C. to yield at least one silanol and at least one alcohol.

45. The method according to claim 44, wherein the mixture used, relative to the total weight of the mixture, includes
≥70 wt. % to ≤90 wt. % of the at least one trialkoxysilane, and
≥10 wt. % to ≤30 wt. %, of the water, wherein the water is used in a stoichiometric amount or in an amount which is overstoichiometric by a factor of ≤1.7 to alkoxy groups of the at least one trialkoxysilane.

46. The method according to claim 44, wherein the at least one trialkoxysilane includes at least one triethoxysilane and/or at least one tripropoxysilane and/or at least one tributoxysilane.

47. The method according to claim 44, wherein the at least one trialkoxysilane includes an organic moiety having at least one epoxy group and/or amino group and/or mercapto group and/or vinyl group.

48. A silanol composition, for application with at least one ceramic and/or metallic filler and/or to a metallic and/or ceramic material, wherein the silanol composition, relative to a total weight of the silanol composition, comprises:
≥30 wt. % to ≤70 wt. % of at least one silanol,
≥25 wt. % to ≤70 wt. % of at least one alcohol, and
≥0 wt. % to ≤20 wt. %, water, wherein a percentage by weight of the at least one silanol, the percentage by weight of the at least one alcohol, and the percentage by weight of water add up to 100 wt. %.

49. The silanol composition according to claim 48, wherein:
the at least one alcohol is ethanol, and/or
the at least one silanol includes at least one silanetriol, and/or
the at least one silanol includes an organic moiety with at least one functional group including at least one epoxy group and/or amino group and/or mercapto group and/or vinyl group.

50. A method for producing a composite composition comprising:
mixing at least one silanol and at least one filler are mixed, wherein, relative to a total weight of the composite composition to be produced, wherein ≥10 wt. % to ≤95 wt. % of the at least one filler, and ≥1 wt. % to ≤15 wt. % of the at least one silanol, are used.

51. The method according to claim 50, wherein at least one alcohol is further added, wherein, relative to the total weight of the composite composition to be produced, ≥1 wt. % to ≤15 wt. %, in particular ≥2 wt. % to ≤12 wt. %, of the at least one alcohol are used.

52. The method according to claim 50, wherein the at least one silanol and/or the at least one alcohol is used in the form of an alcoholic solution, and wherein the at least one filler is added to the alcoholic solution of the at least one silanol.

53. The method according to claim 50, wherein the at least one silanol and/or the at least one alcohol is used in the form of a silanol composition including, relative to a total weight of the composite composition, ≥10 wt. % to ≤95 wt. % of at least one filler, and ≥1 wt. % to ≤15 wt. % of at least one silanol, the silanol composition being produced by converting a mixture of at least one trialkoxysilane and water in a closed system at a temperature of ≥60° C. to yield the least one silanol and the at least one alcohol.

54. The method according to claim 50, wherein the mixing includes stirring under a vacuum.

55. A method for producing a composite and/or a solid structure in the form of a potting and/or casting and/or coating, in which a composite composition including, relative to a total weight of the composite composition, ≥10 wt. % to ≤95 wt. % of at least one filler, and ≥1 wt. % to ≤15 wt. % of at least one silanol is cured at a temperature in a range of ≥130° C.

56. The method according to claim 55, wherein the composite composition is first poured onto a ceramic and/or metallic substrate, and is then cured.

57. The method according to claim 55, wherein the composite composition is dried before curing, wherein the drying takes place at a temperature in a range of ≥25° C. to ≤95° C.

58. The method according to claim 55, wherein the substrate includes at least one electronic and/or electrical component and/or at least one electronic and/or at least one electronic module and/or at least one printed circuit board and/or at least one wire and/or at least one solder.

59. A electronics and/or electrics composite potting comprising a composite composition including, relative to a total weight of the composite composition, ≥10 wt. % to ≤95 wt. % of at least one filler, and ≥1 wt. % to ≤15 wt. % of at least one silanol, cured at a temperature in a range of ≥130° C.

60. The composite composition according to claim 31, wherein the composite composition is used as a potting compound and/or casting compound and/or coating agent for electrics and/or electronics.
